(19) United States
(12) Patent Application Publication
(10) Pub. No.: US 2026/0135478 A1
(43) Pub. Date: May 14, 2026

(54) VOLTAGE BOOSTER AND REFERENCE CONTROL CIRCUIT

(71) Applicant: EMEMORY TECHNOLOGY INC., HSINCHU (TW)

(72) Inventors: CHIA-FU CHANG, HSINCHU COUNTY (TW); CHIA-CHING LI, HSINCHU COUNTY (TW)

(21) Appl. No.: 19/382,928

(22) Filed: Nov. 7, 2025

Related U.S. Application Data
(60) Provisional application No. 63/719,167, filed on Nov. 12, 2024.

(51) Int. Cl. H02M 3/07; H02M 1/00

(52) U.S. Cl. CPC H02M 3/07; H02M 1/0045

(57) ABSTRACT

A voltage booster includes a charge pump, a boost control circuit, a bandgap circuit, a voltage divider, a bandgap buffer, and a reference control circuit. The charge pump generates a pumped voltage according to an input power voltage. The boost control circuit generates an adjustment signal for controlling the charge pump according to a charge pump reference voltage and a feedback voltage of the pumped voltage. The bandgap circuit generates a bandgap voltage according to the pumped voltage. The voltage divider generates an input power reference voltage according to the input power voltage. The bandgap buffer generates a bandgap reference voltage according to the bandgap voltage. The reference control circuit generates the charge pump reference voltage according to the input power reference voltage before the bandgap circuit becomes ready, and generates the charge pump reference voltage according to the bandgap reference voltage after the bandgap circuit is ready.

### CROSS REFERENCE

This application claims the benefit of prior-filed U.S. provisional application No. 63/719,167, filed on November 12, 2024, which is incorporated by reference in its entirety.

### TECHNICAL FIELD

The present disclosure relates to a voltage booster, and more particularly, to voltage booster with a reference control circuit for low power application.

### DISCUSSION OF THE BACKGROUND

In response to the need for low power consumption in electronic devices, integrated circuits (IC) have been re-designed to operate in low voltage environments. While lower voltages are beneficial for reducing power consumption, there are still situations where greater voltages are necessary. In such case, a charge pump for providing a higher voltage is typically adopted.

In general, to dynamically adjust the output voltage and maintain it within a stable range, the charge pump needs to convert its output voltage into a feedback voltage and compare the feedback voltage with a reference voltage so as to achieve a feedback scheme. In such case, how to provide a stable reference voltage becomes a crucial issue for initiating the charge pump and maintaining the stability of the charge pump.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a voltage booster. The voltage booster includes a charge pump, a boost control circuit, a bandgap circuit, a voltage divider, a bandgap buffer, and a reference control circuit. The charge pump generates a pumped voltage according to an input power voltage. The boost control circuit generates an adjustment signal for controlling the charge pump to raise or lower the pumped voltage by comparing a charge pump reference voltage with a feedback voltage generated according to the pumped voltage. The bandgap circuit generates a bandgap voltage according to the pumped voltage. The voltage divider generates an input power reference voltage according to the input power voltage. The bandgap buffer generates a bandgap reference voltage according to the bandgap voltage. The reference control circuit generates the charge pump reference voltage according to the input power reference voltage before the bandgap circuit becomes ready, generates the charge pump reference voltage according to the input power reference voltage and the bandgap reference voltage after the bandgap circuit is ready, and outputs the charge pump reference voltage through an output terminal.

Another aspect of the present disclosure provides a reference control circuit. The reference control circuit provides a charge pump reference voltage to a charge pump so as to adjust the charge pump to generate a pumped voltage according to an input power voltage. The reference control circuit includes a first amplifier, a second amplifier, and a transistor. The first amplifier has a non-inverting input terminal for receiving a bandgap reference voltage generated according to a bandgap voltage outputted by a bandgap circuit, an inverting input terminal, and an output terminal coupled to the inverting input terminal. The second amplifier has a non-inverting input terminal coupled to the output terminal of the first amplifier, an inverting input terminal for receiving an input power reference voltage generated according to the input power voltage, and an output terminal. The transistor has a first terminal for receiving the input power voltage, a second terminal coupled to the output terminal of the first amplifier, and a control terminal coupled to the output terminal of the second amplifier.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 shows a voltage booster according to one embodiment of the present disclosure.

FIG. 2 shows a voltage booster according to another embodiment of the present disclosure.

FIG. 3 shows waveforms of the control signals according to one embodiment of the present disclosure.

FIG. 4 shows a voltage booster according to another embodiment of the present embodiment.

FIG. 5 shows waveforms of the control signals according to one embodiment of the present disclosure.

FIG. 6 shows waveforms of the control signals according to another embodiment of the present disclosure.

### DETAILED DESCRIPTION

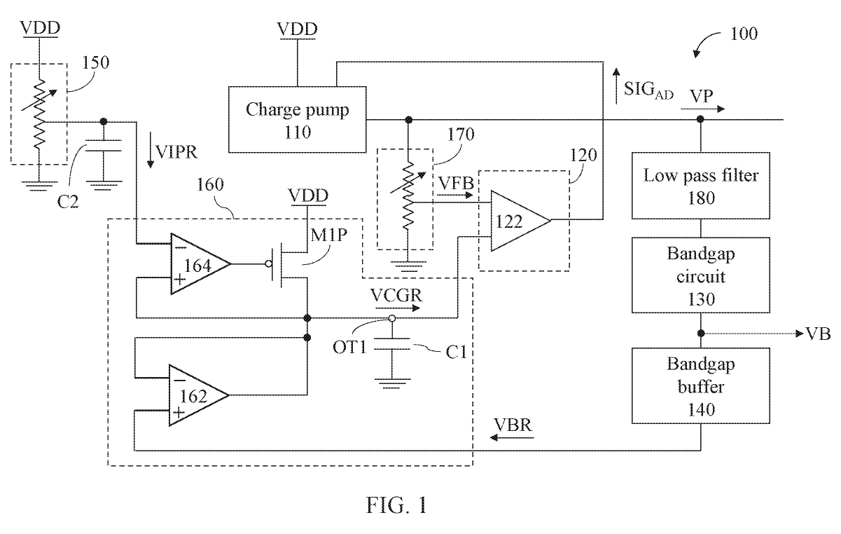

FIG. 1 shows a voltage booster 100 according to one embodiment of the present disclosure. The voltage booster 100 includes a charge pump 110, a boost control circuit 120, a bandgap circuit 130, a bandgap buffer 140, a voltage divider 150, and a reference control circuit 160. In some embodiments, the voltage booster 100 can be employed in a low power application, which operates with low input voltages, for example, the input power voltage VDD. In some embodiments, the input power voltage VDD may vary in a range between 1V to 1.4V. However, the present disclosure is not limited thereto,

In the present embodiment, to support functions requiring higher voltages, the charge pump 110 can receive the input power voltage VDD and generate a pumped voltage VP that is higher than the input power voltage VDD according to the input power voltage VDD. In some embodiments, the pumped voltage VP can be targeted at 1.8V, however, the present disclosure is not limited thereto.

To provide the pumped voltage VP stably, the voltage booster 100 employs the boost control circuit 120 for the feedback scheme of the charge pump 110. For example, the boost control circuit 120 may generate an adjustment signal SIG_{AD} for controlling the charge pump 110 to raise or lower the pumped voltage VP by comparing a charge pump reference voltage VCGR with a feedback voltage VFB. The feedback voltage VFB can be generated according to the pumped voltage VP, and can thus be used to indicate the variation of the pumped voltage VP. On the other hand, the charge pump reference voltage VCGR needs to be maintained in a stable status for indicating the target voltage to be generated by the charge pump 110. In such case, the relation between the feedback voltage VFB and the charge pump reference voltage VCGR can reflect the relation between the pumped voltage VP generated by the charge pump 110 and the target voltage, and therefore, by comparing the feedback voltage VFB with the charge pump reference voltage VCGR, the boost control circuit 120 can generate the adjustment signal SIG_{AD} for controlling the charge pump 110 accordingly. In some embodiments, the boost control circuit 120 can be embedded in the charge pump 110 as a part of the charge pump 110. However, the present disclosure is not limited thereto.

Specifically, the boost control circuit 120 may include a comparator 122 for comparing the feedback voltage VFB with the charge pump reference voltage VCGR. When the feedback voltage VFB is higher than the charge pump reference voltage VCGR, it may imply that the pumped voltage VP has been raised too high, and the boost control circuit 120 can generate the adjustment signal SIG_{AS} so as to have the charge pump 110 lower the pumped voltage VP. Otherwise, when the feedback voltage VFB is lower than the charge pump reference voltage VCGR, it may imply that the pumped voltage VP has been dropped too low, and the boost control circuit 120 can generate the adjustment signal SIG_{AS} so as to have the charge pump 110 raise the pumped voltage VP. As a result, the charge pump 110 can provide the pumped voltage VP in a relatively stable manner.

In the present embodiment, the feedback voltage VFB can be a divisional voltage of the pumped voltage VP generated by a voltage divider 170. In such case, the feedback voltage VFB can be proportioned to the pumped voltage VP so as to indicate the variation of the pumped voltage VP instantly.

It may be noted that, in the feedback scheme provided by the boost control circuit 120, providing a stable voltage for the charge pump reference voltage (VCGR) is crucial for setting a stable reference for the target voltage. In some embodiments, the bandgap circuit 130 that is characterized in its stability for generating the bandgap voltage VB may be adopted to provide such charge pump reference voltage VCGR. For example, the bandgap buffer 140 may be adopted to generate a bandgap reference voltage VBR according to the bandgap voltage VB, and the boost control circuit 120 may receive the bandgap reference voltage VBR as the charge pump reference voltage VCGR to achieve the feedback scheme aforementioned.

However, the bandgap circuit 130 needs to generate the bandgap voltage VB according to the pumped voltage VP. That is, the bandgap circuit 130 needs to wait for the pumped voltage VP before it become ready to generate the bandgap voltage VB. Therefore, in an initial stage before the bandgap circuit 130 is ready to generate the bandgap voltage VB, the boost control circuit 120 may need another source for providing the charge pump reference voltage VCGR. In the present embodiment, to solve this issue, an input power reference voltage VIPR can be generated according to the input power voltage VDD as the charge pump reference voltage VCGR temporarily.

Specifically, the voltage divider 150 can generate the input power reference voltage VIPR that is proportioned to the input power voltage VDD, and the reference control circuit 160 can be adopted to generate the charge pump reference voltage VCGR according to the input power reference voltage VIPR and the bandgap reference voltage VBR.

For example, the reference control circuit 160 can generate the charge pump reference voltage VCGR according to the input power reference voltage VIPR before the bandgap circuit 130 becomes ready, and generate the charge pump reference voltage VCGR according to the input power reference voltage VIPR and the bandgap reference voltage VBR after the bandgap circuit 130 is ready.

In the present embodiment, the reference control circuit 160 includes an output terminal OT1, amplifiers 162, 164, and a transistor M1P. The amplifier 162 has a non-inverting input terminal for receiving the bandgap reference voltage VBR, an inverting input terminal, and an output terminal coupled to the inverting input terminal and the output terminal OT1 of the reference control circuit 160. The amplifier 164 has a non-inverting input terminal coupled to the output terminal of the amplifier 162, an inverting input terminal for receiving the input power reference voltage VIPR, and an output terminal. The transistor M1P has a first terminal for receiving the input power voltage VDD, a second terminal coupled to the output terminal of the amplifier 162, and a control terminal coupled to the output terminal of the amplifier 164. In some embodiments, the transistor M1P can be a P-type transistor.

In such case, when the bandgap reference voltage VBR is lower than the input power reference voltage VIPR, the transistor M1P can be turned on by the amplifier 164, raising up the charge pump reference voltage VCGR to the input power reference voltage VIPR. As a result, the charge pump reference voltage VCGR outputted through the output terminal OT1 can be the higher one of the input power reference voltage VIPR and the bandgap reference voltage VBR.

As a result, before the bandgap circuit 130 can generate the bandgap voltage VB stably or when the bandgap voltage VB is dropped unexpectedly, the reference control circuit 160 can output the input power reference voltage VIPR as the charge pump reference voltage VCGR, so as to maintain the reliability of the voltage booster 100. In the present embodiment, the input power reference voltage VIPR can be set to be equal to the bandgap reference voltage VBR (e.g., both at 0.4V) so that the input power reference voltage VIPR can be adopted as the charge pump reference voltage VCGR when the bandgap voltage VB is unavailable or unstable. However, the input power voltage VDD is provided by external and may not be fixed. In some cases, the input power voltage VDD may vary during operations, and the input power reference voltage VIPR may also vary accordingly. However, whenever the bandgap voltage VB reaches or exceeds the input power reference voltage VIPR, the bandgap reference voltage VBR can be outputted as the charge pump reference voltage VCGR so as to ensure the stability of the pumped voltage VP. Since the reference control circuit 160 provides the charge pump reference voltage VCGR appropriately, the charge pump 110 can accordingly generate a more stable pumped voltage VP.

Furthermore, in some embodiments, the reference control circuit may further include a capacitor C1 having a first terminal coupled to the output terminal OT1 of the reference control circuit 160, and a second terminal for receiving a system reference voltage, such as the ground voltage. The capacitor C1 can help to improve the stability of the charge pump reference voltage VCGR. Similarly, the voltage booster 100 may further include a capacitor C2 coupled between the output terminal of the voltage divider 150 and the system reference voltage for smoothing the input power reference voltage VIPR. In addition, in some embodiments, the voltage booster 100 may further include a low pass filter 180 for filtering the pumped voltage VP before the bandgap circuit 130 receives the pumped voltage VP.

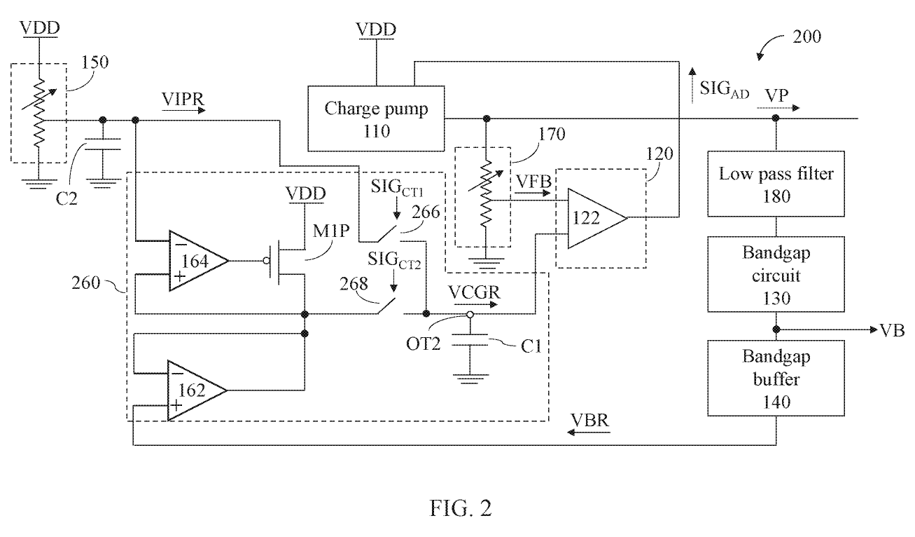

FIG. 2 shows a voltage booster 200 according to another embodiment of the present disclosure. The voltage booster 200 is different from the voltage booster 100 at least in that the reference control circuit 260 of the voltage booster 200 further includes switches 266 and 268. In such case, the switch 266 has a first terminal for receiving the input power reference voltage VIPR, a second terminal coupled to the output terminal OT2 of the reference control circuit 260, and a control terminal for receiving a control signal SIG_{CT1}. The switch 268 has a first terminal coupled to the output terminal of the amplifier 162, a second terminal coupled to the output terminal OT2 of the reference control circuit 260, and a control terminal for receiving a control signal SIG_{CT2}.

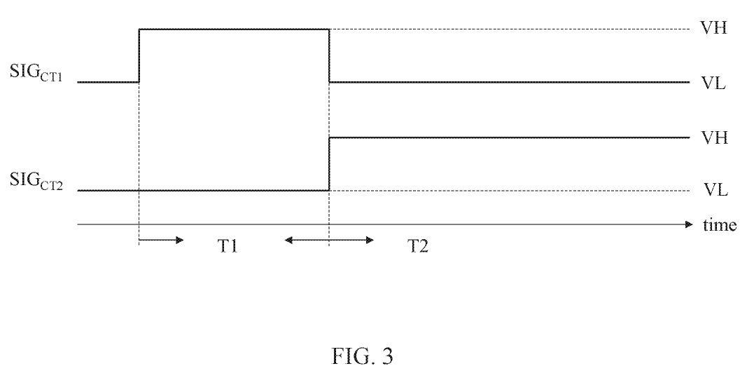

FIG. 3 shows waveforms of the control signals SIG_{CT1} and SIG_{CT2} according to one embodiment of the present disclosure. In the present embodiment, the switch 266 can be turned on when the control signal SIG_{CT1} is at a high voltage VH, and can be turned off when the control signal SIG_{CT1} is at a low voltage VL. Also, the switch 268 can be turned on when the control signal SIG_{CT2} is at the high voltage VH, and can be turned off when the control signal SIG_{CT2} is at the low voltage VL. However, the present disclosure is not limited thereto. In some other embodiments, the switch 266 or 268 may be turned on when receiving the low voltage VL and may be turned off when receiving the high voltage VH. In some embodiments, the switches 266 and 268 can be implemented by N-type transistors or P-type transistors.

In FIG. 3, during a setup period T1 before the bandgap circuit 130 is ready, the control signal SIG_{CT1} is at the high voltage VH and the control signal SIG_{CT2} is at the low voltage VL. Accordingly, the switch 266 is turned on and the switch 268 is turned off. As a result, the input power reference voltage VIPR is outputted as the charge pump reference voltage VCGR through the output terminal OT2 of the reference control circuit 260.

Subsequently, during a period T2 after the setup period T1, the bandgap circuit 130 is ready, the control signal SIG_{CT1} is changed to the low voltage VL and the control signal SIG_{CT2} is changed to the high voltage VH. Accordingly, the switch 268 is turned on and the switch 266 is turned off. As a result, the bandgap reference voltage VBR is outputted as the charge pump reference voltage VCGR through the output terminal OT2 of the reference control circuit 260.

In such case, before the bandgap circuit 130 can generate the bandgap voltage VB stably, the reference control circuit 260 can output the input power reference voltage VIPR as the charge pump reference voltage VCGR. Also, when the bandgap voltage VB becomes stable, the reference control circuit 260 may select the bandgap reference voltage VBR as the charge pump reference voltage VCGR so as to ensure the stability of the pumped voltage VP. Since the reference control circuit 260 provides the charge pump reference voltage VCGR appropriately, the voltage booster 200 can accordingly generate a more stable pumped voltage VP.

In some embodiments, the duration of the setup period T1 can be determined by the setup time required by the bandgap circuit 130, so as to ensure that the reference control circuit 260 can output the bandgap reference voltage VBR when the bandgap circuit 130 is ready and become stable. Furthermore, in some embodiments, the voltage booster 200 may further include a controller for generating the control signals SIG_{CT1} and SIG_{CT2}, however, the controller is not shown in FIG. 2 for brevity.

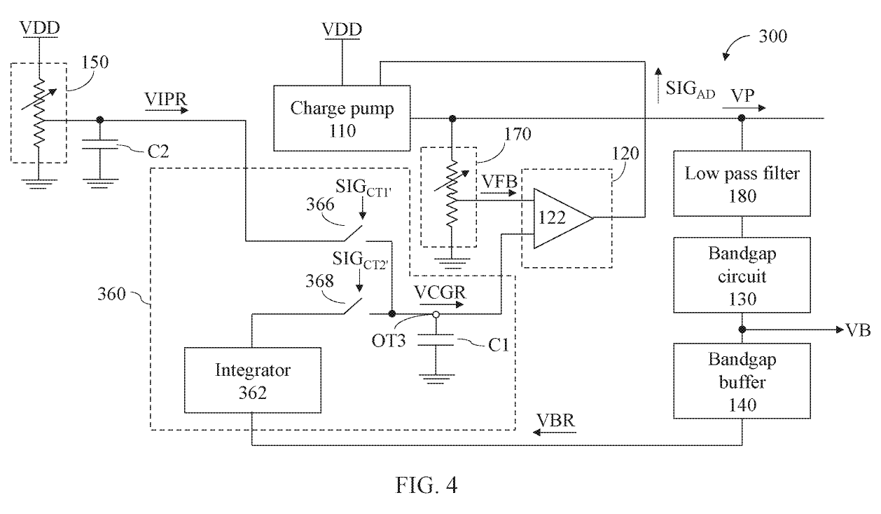

FIG. 4 shows a voltage booster 300 according to another embodiment of the present embodiment. The voltage booster 300 is different from the voltage booster 200 at least in that the reference control circuit 360 includes an integrator 362. In some embodiments, the integrator 362 may include capacitor(s), amplifier(s) and/or some other suitable components for reducing the ripples of the bandgap reference voltage VBR.

Specifically the integrator 362 has an input terminal for receiving the bandgap reference voltage VBR, and an output terminal. The switch 366 has a first terminal for receiving the input power reference voltage VIPR, a second terminal coupled to the output terminal OT3 of the reference control circuit 360, and a control terminal for receiving a control signal SIG_{CT1'}. The switch 368 has a first terminal coupled to the output terminal of the integrator 362, a second terminal coupled to the output terminal OT3 of the reference control circuit 360, and a control terminal for receiving a control signal SIG_{CT2'}.

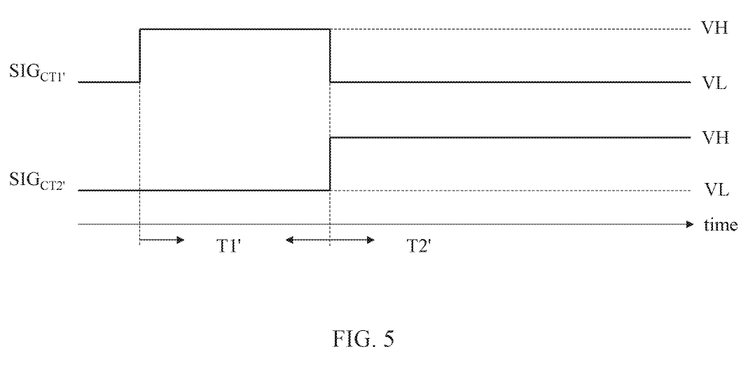

FIG. 5 shows waveforms of the control signals SIG_{CT1'} and SIG_{CT2'} according to one embodiment of the present disclosure. In the present embodiment, the switch 366 can be turned on when the control signal SIG_{CT1'} is at the high voltage VH, and can be turned off when the control signal SIG_{CT1'} is at the low voltage VL. Also, the switch 368 can be turned on when the control signal SIG_{CT2'} is at the high voltage VH, and can be turned off when the control signal SIG_{CT2'} is at the low voltage VL. However, the present disclosure is not limited thereto.

In FIG. 5, during a setup period T1' before the bandgap circuit 130 is ready, the control signal SIG_{CT1'} is at the high voltage VH and the control signal SIG_{CT2'} is at the low voltage VL. Accordingly, the switch 366 is turned on and the switch 368 is turned off. As a result, the input power reference voltage VIPR is outputted as the charge pump reference voltage VCGR through the output terminal OT3 of the reference control circuit 360.

Subsequently, during a period T2' after the setup period T1, the bandgap circuit 130 is ready, the control signal SIG_{CT1'} is changed to the low voltage VL and the control signal SIG_{CT2'} is changed to the high voltage VH. Accordingly, the switch 368 is turned on and the switch 366 is turned off. As a result, the bandgap reference voltage VBR is outputted as the charge pump reference voltage VCGR through the output terminal OT3 of the reference control circuit 360.

In such case, before the bandgap circuit 130 can generate the bandgap voltage VB stably, the reference control circuit 360 can output the input power reference voltage VIPR as the charge pump reference voltage VCGR. Also, when the bandgap voltage VB becomes stable, the reference control circuit 360 may select the bandgap reference voltage VBR as the charge pump reference voltage VCGR so as to ensure the stability of the pumped voltage VP. Since the reference control circuit 360 provides the charge pump reference voltage VCGR appropriately, the voltage booster 300 can accordingly generate a more stable pumped voltage VP.

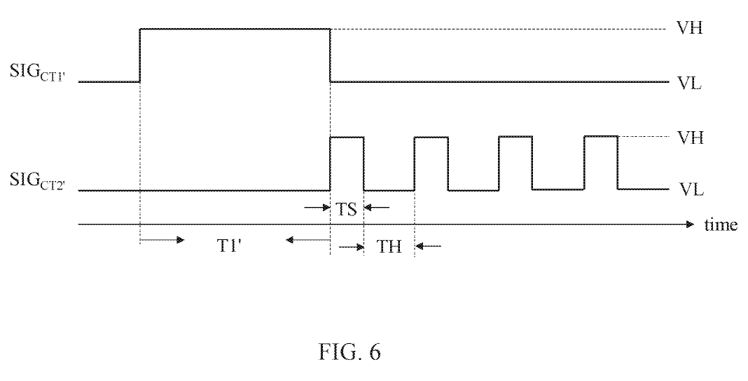

FIG. 6 shows waveforms of the control signals SIG_{CT1'} and SIG_{CT2'} according to another embodiment of the present disclosure. As shown in FIG. 6, during the setup period T1' before the bandgap circuit 130 is ready, the control signal SIG_{CT1'} is at the high voltage VH and the control signal SIG_{CT2'} is at the low voltage VL. Accordingly, the switch 366 is turned on and the switch 368 is turned off. As a result, the input power reference voltage VIPR is outputted as the charge pump reference voltage VCGR through the output terminal OT3 of the reference control circuit 360.

However, unlike the waveforms shown in FIG. 5, after the setup period T1' in FIG. 6, the control signal SIG_{CT2'} can toggle between the high voltage VH and the low voltage VL so as to turn on and turn off the switch 368 repeatedly. In such case, the bandgap reference voltage VBR may not be provided to the boost control circuit 120 continuously so as to avoid the ripples of the bandgap reference voltage VBR from affecting the operation of the boost control circuit 120. In some embodiments, the duty cycle of the control signal SIG_{CT2'} after the setup period T1' is less than 50%. That is, the duration TS that the control signal SIG_{CT2'} is at the high voltage VH can be shorter than the duration TH that the control signal SIG_{CT2'} is at the low voltage VL. However, the present disclosure is not limited thereto.

In summary, the voltage booster and the reference control circuit provided by the embodiments of the present disclosure can provide the charge pump reference voltage according to the input power reference voltage and the bandgap reference voltage appropriately, thereby allowing the charge pump to generate the pumped voltage stably.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A voltage booster comprising:
a charge pump configured to generate a pumped voltage according to an input power voltage;
a boost control circuit configured to generate an adjustment signal, by comparing a charge pump reference voltage with a feedback voltage derived from the pumped voltage, to control the charge pump;
a bandgap circuit configured to generate a bandgap voltage according to the pumped voltage;
a first voltage divider configured to generate an input power reference voltage according to the input power voltage;
and
a reference control circuit comprising an output terminal configured to output the charge pump reference voltage according to the input power reference voltage before the bandgap circuit becomes ready, and output the charge pump reference voltage according to the higher one of the input power reference voltage and a bandgap reference voltage derived from the bandgap voltage after the bandgap circuit is ready.

2. The voltage booster of claim 1, wherein the reference control circuit comprises:
a first amplifier having a non-inverting input terminal configured to receive the bandgap reference voltage, an inverting input terminal, and an output terminal coupled to the inverting input terminal;
a second amplifier having a non-inverting input terminal coupled to the output terminal of the first amplifier, an inverting input terminal configured to receive the input power reference voltage, and an output terminal; and
a transistor having a first terminal configured to receive the input power voltage, a second terminal coupled to the output terminal of the first amplifier, and a control terminal coupled to the output terminal of the second amplifier.

3. The voltage booster of claim 2, wherein the output terminal of the first amplifier is the output terminal of the reference control circuit.

4. The voltage booster of claim 2, wherein the transistor is a P-type transistor, and when the bandgap reference voltage is lower than the input power reference voltage, the transistor is turned on by the second amplifier so as to raise the charge pump reference voltage.

5. The voltage booster of claim 2, wherein the reference control circuit further comprises:
a first switch having a first terminal configured to receive the input power reference voltage, a second terminal coupled to the output terminal of the reference control circuit, and a control terminal configured to receive a first control signal; and
a second switch having a first terminal coupled to the output terminal of the first amplifier, a second terminal coupled to the output terminal of the reference control circuit, and a control terminal configured to receive a second control signal.

6. The voltage booster of claim 5, wherein the first control signal is configured to turn on the first switch during a setup period before the bandgap circuit is ready, and the second control signal is configured to turn on the second switch after the setup period.

7. The voltage booster of claim 1, wherein the reference control circuit comprises:
an integrator having an input terminal configured to receive the bandgap reference voltage, and an output terminal;
a first switch having a first terminal configured to receive the input power reference voltage, a second terminal coupled to the output terminal of the reference control circuit, and a control terminal configured to receive a first control signal; and
a second switch having a first terminal coupled to the output terminal of the integrator, a second terminal coupled to the output terminal of the reference control circuit, and a control terminal configured to receive a second control signal.

8. The voltage booster of claim 7, wherein the first control signal is configured to turn on the first switch during a setup period before the bandgap circuit is ready, and the second control signal is configured to turn on the second switch after the setup period.

9. The voltage booster of claim 7, wherein the first control signal is configured to turn on the first switch during a setup period before the bandgap circuit is ready, and after the setup period, the second control signal is configured to turn on and turn off the second switch repeatedly.

10. The voltage booster of claim 9, wherein after the setup period, a duty cycle of the second control signal is less than 50%.

11. The voltage booster of claim 1, further comprising a second voltage divider configured to generate the feedback voltage according to the pumped voltage.

12. The voltage booster of claim 1, wherein the boost control circuit comprises a comparator configured to generate the adjustment signal so as to lower the pumped voltage when the feedback voltage is higher than the charge pump reference voltage and to raise the pumped voltage when the feedback voltage is lower than the charge pump reference voltage.

13. The voltage booster of claim 1, wherein the reference control circuit comprises a capacitor having a first terminal coupled to the output terminal of the reference control circuit, and a second terminal configured to receive a system reference voltage.

14. The voltage booster of claim 1, further comprising a low pass filter configured to filter the pumped voltage before the bandgap circuit receives the pumped voltage.

15. A reference control circuit configured to provide a charge pump reference voltage to a charge pump so as to adjust the charge pump to generate a pumped voltage according to an input power voltage, the reference control circuit comprising:
a first amplifier having a non-inverting input terminal configured to receive a bandgap reference voltage generated according to a bandgap voltage outputted by a bandgap circuit, an inverting input terminal, and an output terminal coupled to the inverting input terminal;
a second amplifier having a non-inverting input terminal coupled to the output terminal of the first amplifier, an inverting input terminal configured to receive an input power reference voltage generated according to the input power voltage, and an output terminal; and
a transistor having a first terminal configured to receive the input power voltage, a second terminal coupled to the output terminal of the first amplifier, and a control terminal coupled to the output terminal of the second amplifier.

16. The reference control circuit of claim 15, wherein the output terminal of the first amplifier is coupled to the output terminal of the reference control circuit.

17. The reference control circuit of claim 15, wherein the transistor is a P-type transistor, and when the bandgap reference voltage is lower than the input power reference voltage, the transistor is turned on by the second amplifier so as to raise the charge pump reference voltage.

18. The reference control circuit of claim 15, wherein the reference control circuit further comprises:
a first switch having a first terminal configured to receive the input power reference voltage, a second terminal coupled to the output terminal of the reference control circuit, and a control terminal configured to receive a first control signal; and
a second switch having a first terminal coupled to the output terminal of the first amplifier, a second terminal coupled to the output terminal of the reference control circuit, and a control terminal configured to receive a second control signal.

19. The reference control circuit of claim 18, wherein the first control signal is configured to turn on the first switch during a setup period before the bandgap circuit is ready, and the second control signal is configured to turn on the second switch after the setup period.
